(19) United States
(12) Patent Application Publication
(10) Pub. No.: US 2012/0162501 A1
(43) Pub. Date: Jun. 28, 2012

(54) ELECTRONIC DEVICE AND IMAGING DEVICE

(75) Inventors: Kiyoshi YOKOTA, Osaka (JP); Hiroshi Nakamoto, Osaka (JP)

(73) Assignee: Panasonic Corporation, Osaka (JP)

(21) Appl. No.: 13/118,577

(22) Filed: May 31, 2011

(30) Foreign Application Priority Data
Dec. 27, 2010 (JP) 2010-290175

(51) Int. Cl. H04N 5/225; H05K 7/00

(52) U.S. Cl. 348/374; 361/807; 348/E05.024

(57) ABSTRACT

An electronic device comprises a housing, a sliding cover and an internal member. The housing includes a plate-like member that defines a slide opening. The sliding cover includes a cover component disposed on the plate-like member and slidably attached to the slide opening, a detected component fixed to the cover component and extending into the housing, and a first restrictor fixed to the cover component. The internal member is disposed inside the housing and includes a detector switch having a contact component configured to contact the detected component when the detected component is at a specific position and a second restrictor adjacent to the first restrictor when the detected component is at the specific position. The detector switch detects when the contact component contacts the detected component. The first and second restrictors are configured to restrict movement of the plate-like member when the detected component is at the specific position.

### CROSS-REFERENCE TO RELATED APPLICATIONS

This application claims priority under 35 U.S.C. §119 to Japanese Patent Application No. 2010-290175, filed on Dec. 27, 2010. The entire disclosure of Japanese Patent Applications No. 2010-290175 is hereby incorporated herein by reference.

### BACKGROUND

1. Technical Field

The technology disclosed herein relates to an electronic device and an imaging device comprising a sliding cover.

2. Background Information

In the past, there was a known digital camera comprising a front plate that constitutes part of a housing, a lens that is fixed to the front plate, and a sliding cover that is slidably attached to an opening formed in the front plate (see Japanese Laid-Open Patent Application 2010-210936). With this digital camera, the lens can be exposed by sliding the sliding cover.

### SUMMARY

With the digital camera discussed herein above, it is possible to employ a mechanism that can be used to detect whether the camera's power supply is on/off or whether, according to the amount of exposure, the camera lens is opened/closed. For instance, the mechanism can include a detector switch and a detected component. The detector switch can have a rotatable lever that protrudes from a sliding cover into the housing. When the rotatable lever is depressed by the detected component, it can be determined whether, for example, the power supply is on or whether the lens is opened.

However, it has been discovered that if the digital camera is subject to an external force (e.g., an impact force caused by dropping the camera), there is a risk that the detected component could be separated from the lever as the front plate bows outward. If the front plate elastically recovers in this state, the lever will be pushed in a non-rotatable direction by the detected component, and the detector switch will end up being damaged.

The technology disclosed herein is conceived in light of the above situation, and it is one object thereof to provide an electronic device and an imaging device in which damage to a detector switch can be reduced.

The electronic device disclosed herein comprises a housing, a sliding cover and an internal member. The housing includes a plate-like member that defines a slide opening. The sliding cover includes a cover component disposed on the plate-like member and slidably attached to the slide opening, a detected component fixed to the cover component and extending into the housing, and a first restrictor fixed to the cover component. The internal member is disposed inside the housing and includes a detector switch having a contact component configured to contact the detected component when the detected component is at a specific position and a second restrictor adjacent to the first restrictor when the detected component is at the specific position. The detector switch detects when the contact component contacts the detected component. The first and second restrictors are configured to restrict movement of the plate-like member when the detected component is at the specific position.

With this electronic device, damage to the detector switch can be reduced.

These and other objects, features, aspects and advantages of the technology disclosed herein will become apparent to those skilled in the art from the following detailed description, which, taken in conjunction with the annexed drawings, discloses a preferred and example embodiments of the present invention.

### BRIEF DESCRIPTION OF DRAWINGS

Referring now to the attached drawings which form a part of this original disclosure:

FIG. 1A and FIG. 1B are oblique views of a digital camera;

FIG. 2A and FIG. 2B are front views of the digital camera;

FIG. 3 is an exploded oblique view of the digital camera;

FIG. 4 is a rear view of a front plate;

FIG. 5A and FIG. 5B are oblique views of a sliding cover;

FIG. 6 is an oblique view of a plastic frame;

FIG. 7 is a detail enlargement of FIG. 6;

FIG. 8A and FIG. 8B are schematic diagrams showing the positional relation between a lever and a knob;

FIG. 9A is cross section along the IXa-IXa line in FIG. 2A, and FIG. 9B is cross section along the IXb-IXb line in FIG. 2A; and

FIG. 10A is cross section along the Xa-Xa line in FIG. 2B, and FIG. 10B is cross section along the Xb-Xb line in FIG. 2B.

### DETAILED DESCRIPTION OF EMBODIMENTS

Selected embodiments will now be explained with reference to the drawings. It will be apparent to those skilled in the art from this disclosure that the following descriptions of the embodiments are provided for illustration only and not for the purpose of limiting the invention as defined by the appended claims and their equivalents.

In the following embodiments, a digital camera will be used as an example in describing an imaging device. In the following description, the following positional terms “front”, “rear”, “down”, “right”, and “left” are used with reference to a digital camera in its normal orientation to the subject (hereinafter also referred to as landscape orientation). In the following embodiment, the open state of the sliding cover of the digital camera corresponds to a “power-on state,” and the closed state of the sliding cover of the digital camera corresponds to a “power-off state.”

Overall Configuration of Digital Camera 100

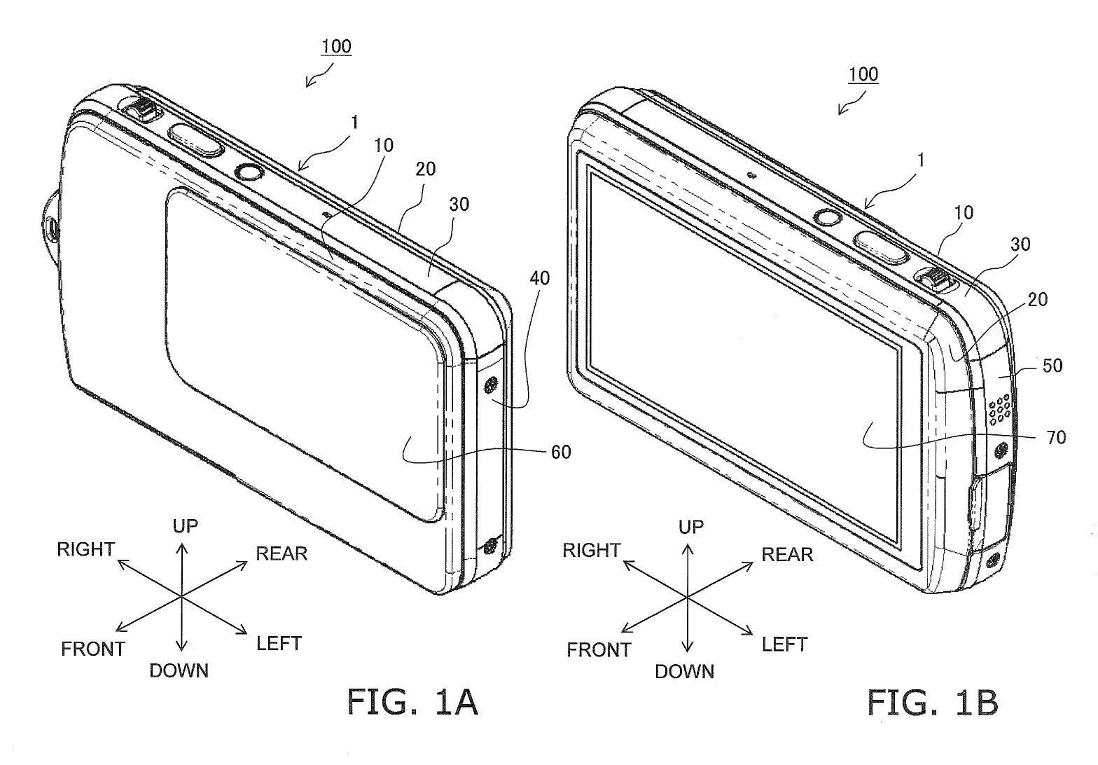

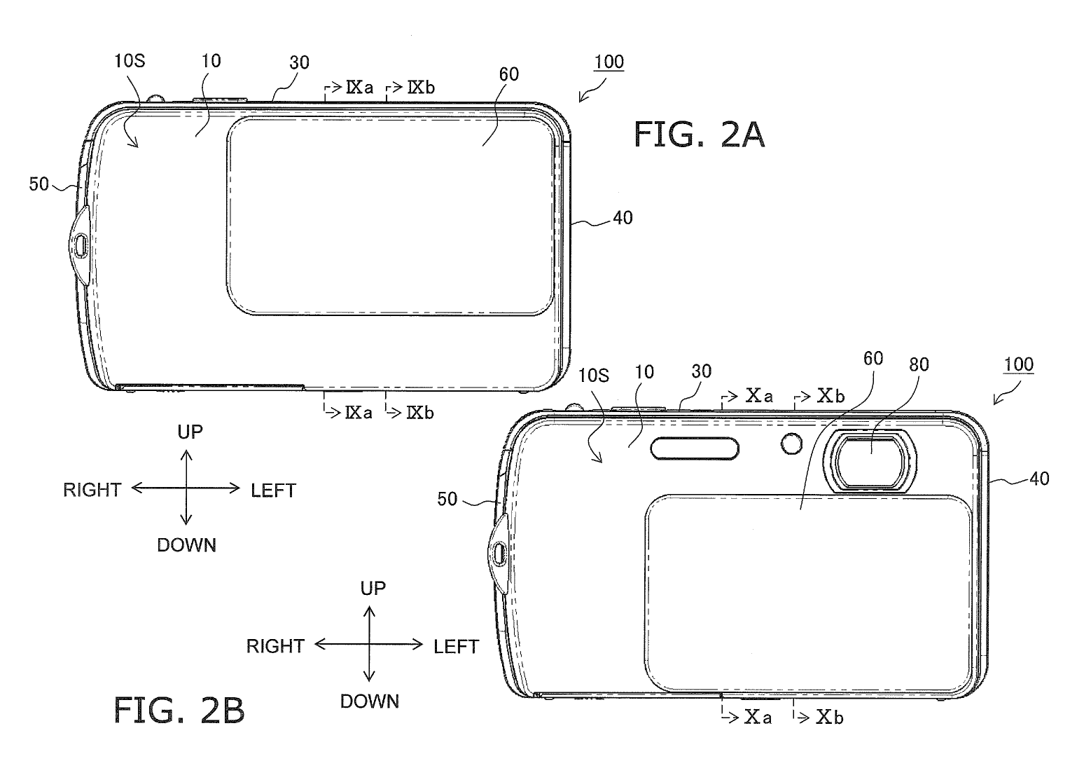

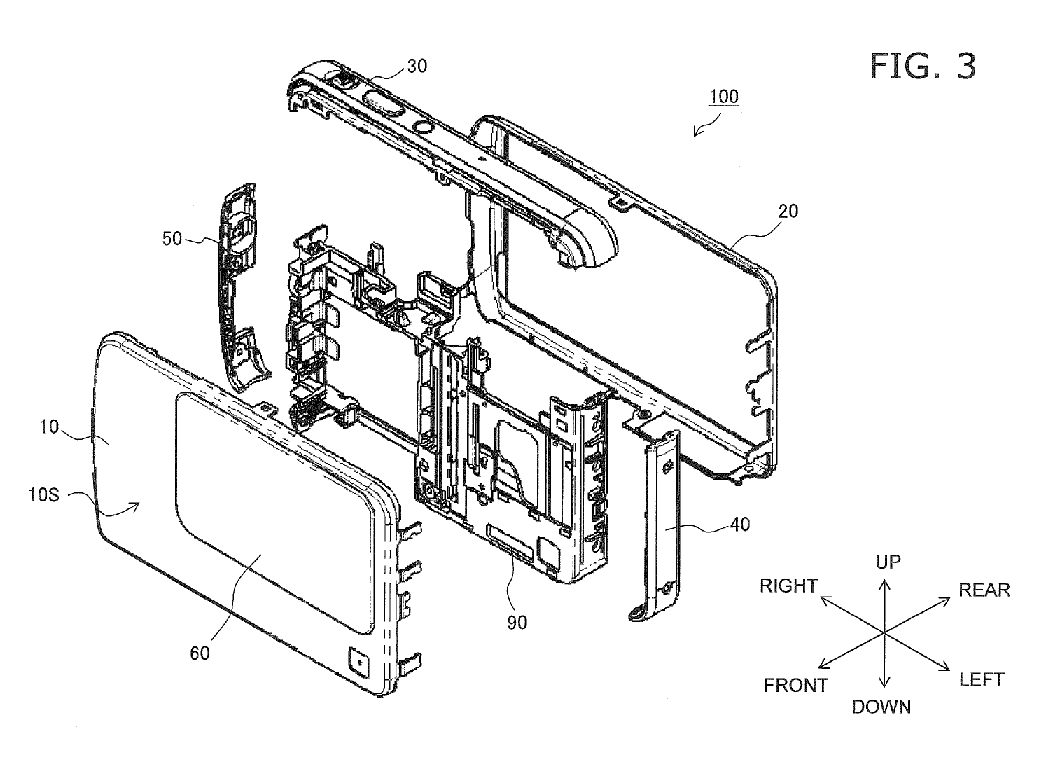

The overall configuration of the digital camera 100 pertaining to the embodiment will be described through reference to the drawings. FIG. 1A is an oblique view of the digital camera 100 pertaining to the embodiment as seen from the front. FIG. 1B is an oblique view of the digital camera 100 pertaining to the embodiment as seen from the rear. FIG. 2A is a front view of the power-off state of the digital camera 100 pertaining to the embodiment. FIG. 2B is a front view of the power-on state of the digital camera 100 pertaining to the embodiment. FIG. 3 is an exploded oblique view of the digital camera 100 pertaining to the embodiment as seen from the front. In FIG. 3, a monitor 70 and a lens 80 are not shown.

The digital camera 100 comprises a front plate 10 (one example of a “plate-like member”), a rear plate 20, a top plate 30, a first side plate 40, a second side plate 50, a sliding cover 60, a monitor 70, a lens 80, and a plastic frame 90 (an example of an “internal member”). The front plate 10, the rear plate 20, the top plate 30, the first side plate 40, and the second side plate 50 constitute the “housing” pertaining to this embodiment.

The front plate 10 is disposed in front of the plastic frame 90. The front plate 10 has an outer face 10S. The rear plate 20 is disposed to the rear of the plastic frame 90. The top plate 30 is disposed above the plastic frame 90. The first side plate 40 is disposed to the left of the plastic frame 90. The second side plate 50 is disposed to the right of the plastic frame 90. The sliding cover 60 is attached to the front plate 10 slidably in the up and down direction. The sliding cover 60 is slid upward to create a closed state, and is slid downward to create an open state. The configuration of the sliding cover 60 will be discussed below. The monitor 70 is disposed between the plastic frame 90 and the rear plate 20. The lens 80 is disposed between the plastic frame 90 and the front plate 10. The lens 80 is covered by the sliding cover 60 when the sliding cover 60 is in its closed state, and is exposed from the sliding cover 60 when the sliding cover 60 is in its open state. The plastic frame 90 is disposed inside the housing. The plastic frame 90 supports the various plates constituting the housing from the inside of the housing.

Configuration of Front Plate 10

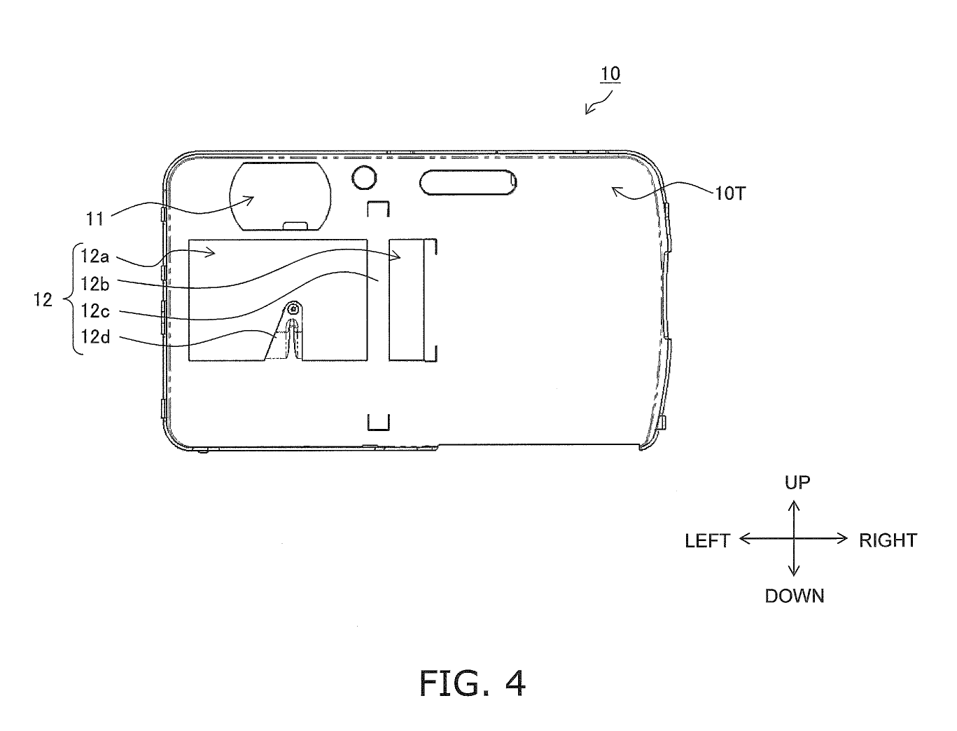

The configuration of the front plate 10 pertaining to the embodiment will be described through reference to the drawings. FIG. 4 is a rear view of the front plate 10 pertaining to the embodiment. The front plate 10 has an inner face 10T, a lens opening 11, and a slide opening 12.

The lens opening 11 is formed in the upper left part of the inner face 10T. External light is incident on the lens 80 through the lens opening 11.

The slide opening 12 has a first opening 12a, a second opening 12b, a slide rail 12c, and a locking protrusion 12d. The first opening 12a is formed below the lens opening 11. The first opening 12a has a rectangular shape that extends in the left and right direction. The second opening 12b is formed in the center of the inner face 10T. The second opening 12b has a rectangular shape that extends in the up and down direction. The slide rail 12c is formed between the first opening 12a and the second opening 12b, and separates the two. The locking protrusion 12d protrudes from the lower edge of the first opening 12a into the middle of the first opening 12a.

Configuration of Sliding Cover 60

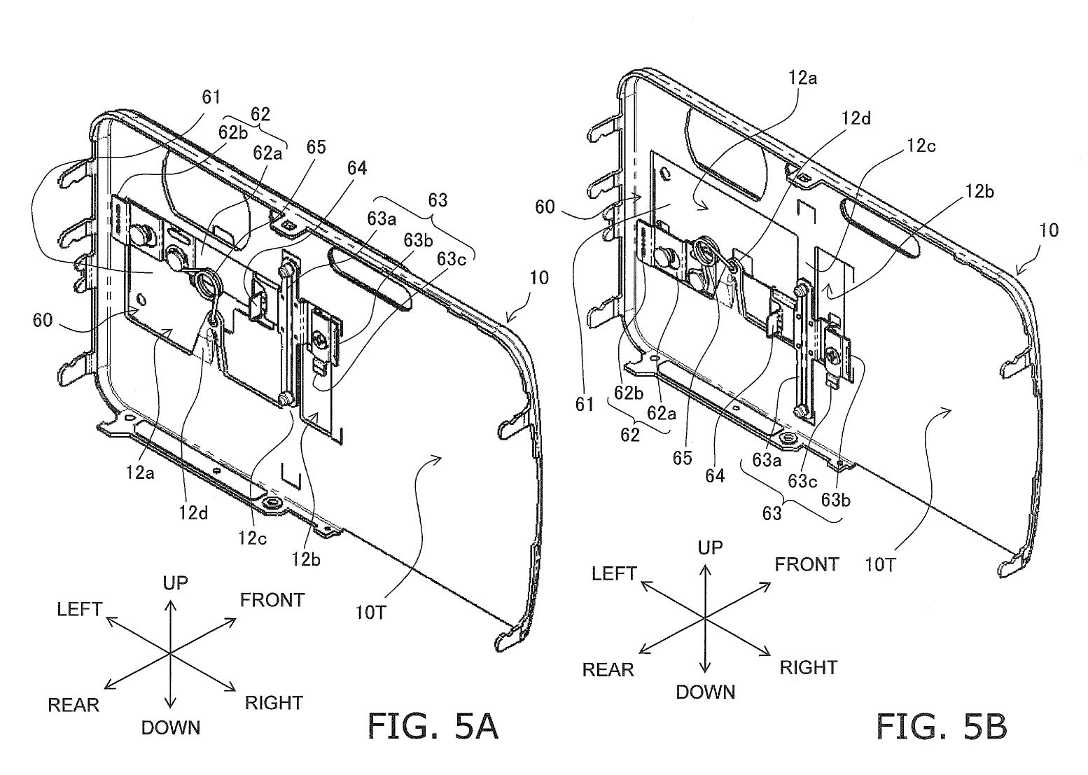

The configuration of the sliding cover 60 pertaining to the embodiment will be described through reference to the drawings. FIG. 5A is an oblique view showing the closed state of the sliding cover 60 (that is, a power-off state). FIG. 5B is an oblique view showing the open state of the sliding cover 60 (that is, a power-on state).

The sliding cover 60 comprises a cover 61, a first sliding component 62, a second sliding component 63, a knob 64 (one example of a “detected component”), and a spring 65.

The cover 61 is a plate-like member that is disposed on the outer face 10S (see FIG. 1) of the front plate 10. The cover 61 is attached to the slide opening 12 slidably in the up and down direction.

The first sliding component 62 is disposed in the first opening 12a, and is fixed to the cover 61. The first sliding component 62 has a base plate 62a and a left locking component 62b. The base plate 62a is disposed along the cover 61. The left locking component 62b protrudes to the left from the base plate 62a. The left locking component 62b is disposed above the inner face 10T of the front plate 10.

The second sliding component 63 has a slider 63a, a right locking component 63b, and a protruding component 63c (an example of a “first restrictor”). The slider 63a is disposed on the slide rail 12c, and is fixed to the cover 61. The slider 63a slides over the slide rail 12c in the up and down direction. The right locking component 63b protrudes to the right from the slider 63a. The right locking component 63b is disposed above the inner face 10T of the front plate 10. The protruding component 63c extends downward from the right locking component 63b. The protruding component 63c is disposed above the middle part of the inner face 10T of the front plate 10 in the left and right direction. The protruding component 63c is formed in the up and down direction. The protruding component 63c is disposed above the inner face 10T of the front plate 10.

The knob 64 is fixed to the cover 61. The knob 64 protrudes from the cover 61 into the housing. The knob 64 is a projection formed in the front and rear direction.

The spring 65 is attached to the locking protrusion 12d and the base plate 62a of the first sliding component 62. The spring 65 imparts a biasing force to the cover 61 when the cover 61 is slid up and down by the user.

Configuration of Plastic Frame 90

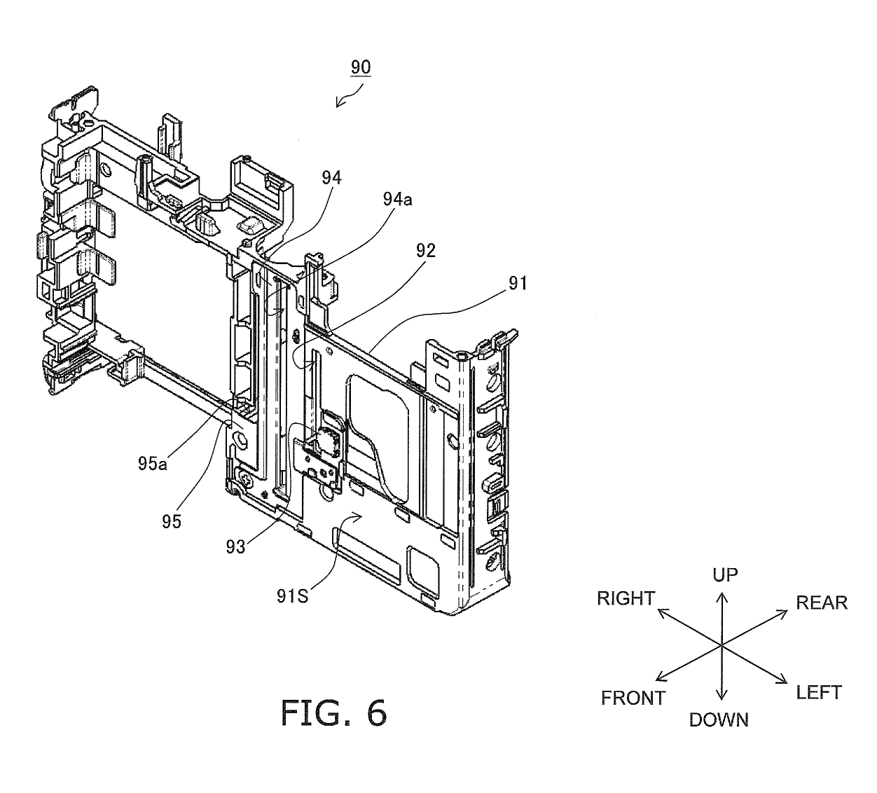

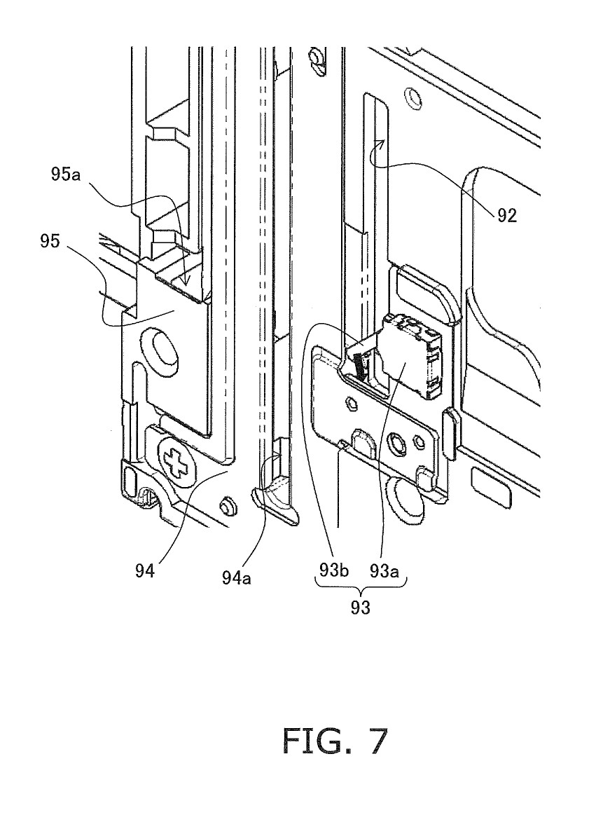

The configuration of the plastic frame 90 pertaining to the embodiment will be described through reference to the drawings. FIG. 6 is an oblique view of the plastic frame 90 pertaining to the embodiment, as seen from the front. FIG. 7 is a detail view of FIG. 6.

The plastic frame 90 comprises a frame main body 91, a knob groove 92, a detector switch 93, a slider guide plate 94, and a blocking plate 95 (an example of a “second restrictor”).

The frame main body 91 is made from a resin material. The frame main body 91 supports the various plates that make up the housing (the front plate 10, the rear plate 20, the top plate 30, the first side plate 40, and the second side plate 50) from inside the housing. The frame main body 91 has an opposite face 91S that is opposite the inner face 10T of the front plate 10.

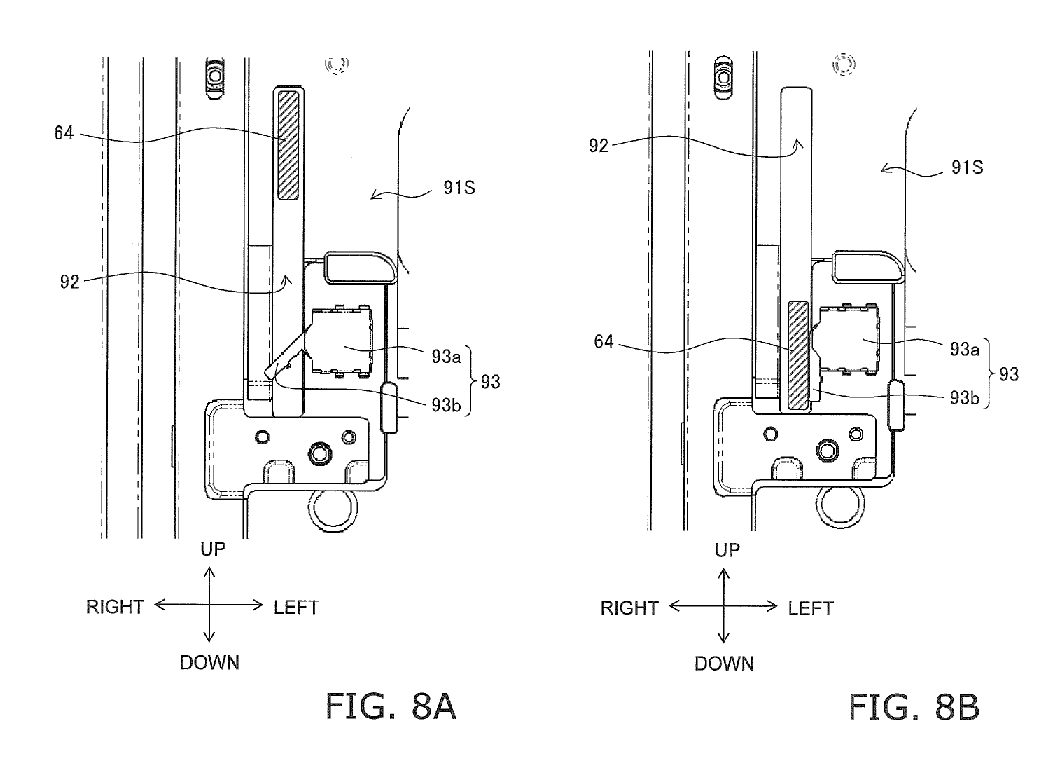

The knob groove 92 is formed along the up and down direction in the frame main body 91. The knob 64 is inserted into the knob groove 92 (see FIG. 8). The knob 64 is able to move in the up and down direction within the knob groove 92.

The detector switch 93 is disposed on the opposite face 91S of the frame main body 91. As shown in FIG. 7, the detector switch 93 comprises a main body 93a and a lever 93b (one example of a “contact component”). The main body 93a is fixed to the opposite face 91S. The lever 93b is rotatably supported by the main body 93a. In this embodiment, the lever 93b rotates around an axis that is parallel to a direction that is perpendicular to the outer face 10S of the front plate 10 (one example of a “plate-like member”), that is, the front and rear direction.

FIGS. 8A and 8B here are schematic diagrams showing the positional relation between the lever 93b (one example of a “contact component”) and the knob 64 (one example of a “detected component”). In FIG. 8A, the sliding cover 60 is in its closed state, and in FIG. 8B the sliding cover 60 is in its open state.

As shown in FIG. 8A, when the sliding cover 60 is in its closed state, the knob 64 is located at the uppermost position. The lever 93b is located under the knob 64 located at the uppermost position, and does not come into contact with the knob 64. The lever 93b passes over the knob groove 92.

As shown in FIG. 8B, when the sliding cover 60 is in its open state, the knob 64 is located at the lowermost position (one example of a “specific position”). The lever 93b comes into contact with the knob 64 located at the lowermost position. The lever 93b is rotated downward by the knob 64 that moves from the uppermost position to the lowermost position. This turns on the power to the digital camera 100. Also, the lever 93b returns to its original position (a position passing over the knob groove 92) when the knob 64 moves upward. This turns off the power to the digital camera 100.

The detector switch 93 detects that the lever 93b has come into contact with the knob 64 according to the downward rotation of the lever 93b. Here, a power supply controller (not shown) connected to the detector switch 93 starts the supply of power to the monitor 70 or a controller (not shown).

The slider guide plate 94 is attached to the opposite face 91S of the frame main body 91. The slider guide plate 94 has a slider groove 94a. The slider groove 94a is formed in the up and down direction in the slider guide plate 94. The slider 63a is inserted into the slider groove 94a. The slider 63a is able to move in the up and down direction in the slider groove 94a.

A blocking plate 95 (one example of a “second restrictor”) is opposite the inner face 10T of the front plate 10. The blocking plate 95 forms part of the opposite face 91S of the frame main body 91. The blocking plate 95 forms a holding space 95a behind the blocking plate 95. The holding space 95a is formed in the up and down direction. The holding space 95a is a space for holding the protruding component 63c (one example of a “first restrictor”) of the second sliding component 63 when the knob 64 is located at the lowermost position (see FIG. 8B).

The blocking plate 95 is also adjacent to the protruding component 63c when the knob 64 is located at the lowermost position (see FIG. 7b). More specifically, the blocking plate 95 is located in front of the protruding component 63c when the knob 64 is located at the lowermost position. Specifically, the blocking plate 95 is disposed between the protruding component 63c and the front plate 10. This restricts the forward movement of the protruding component 63c, that is, restricts the front plate 10 from moving away from the plastic frame 90.

Moreover, the blocking plate 95 and the protruding component 63c are not in contact with each other, and a specific gap is provided between the blocking plate 95 and the protruding component 63c. Accordingly, the front plate 10 can move forward and backward over the range of the specific gap with respect to the plastic frame 90. In other words, the blocking plate 95 and the protruding component 63c restrict the front plate 10 from moving away from the plastic frame 90 by more than a specific gap.

Operation of Protruding component 63c and Knob 64

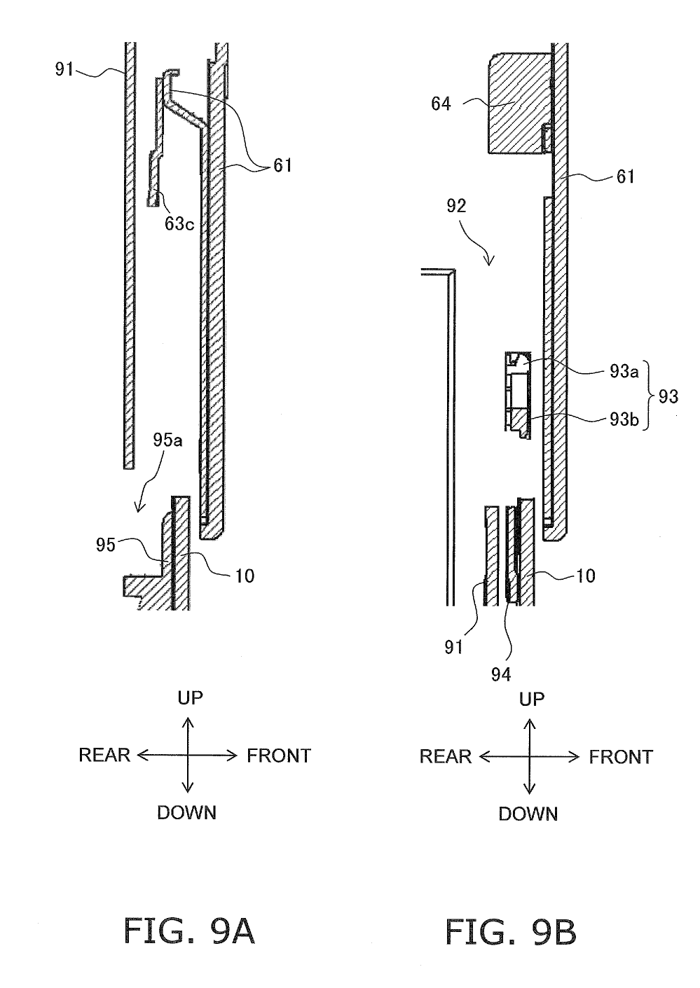

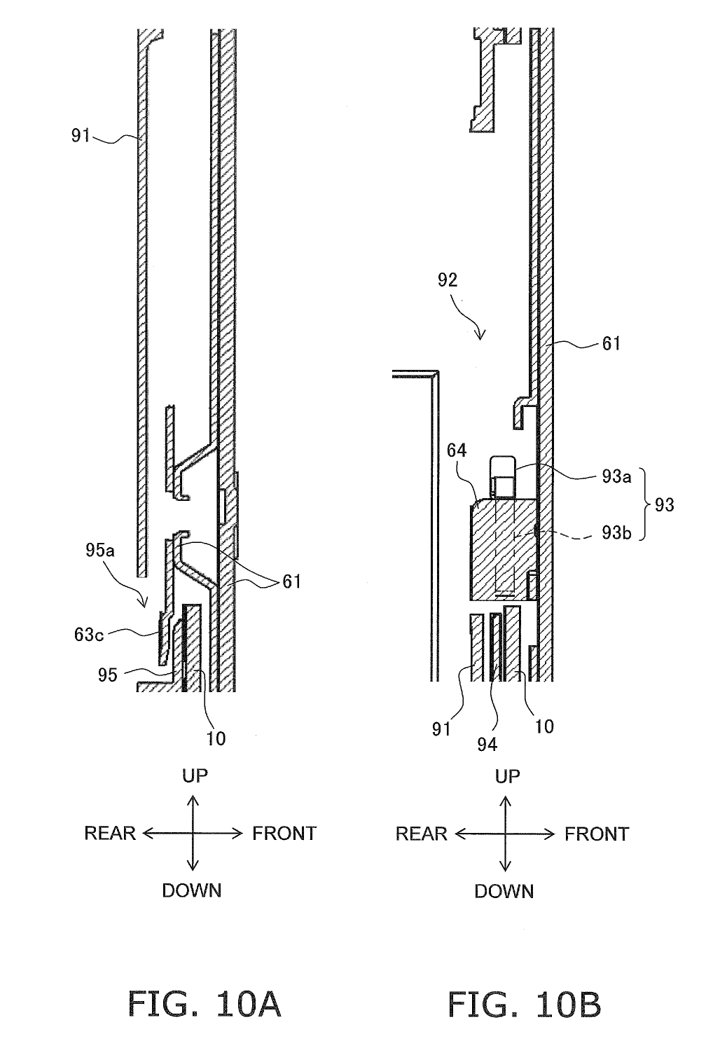

The operation of the protruding component 63c and the knob 64 pertaining to the embodiment will be described through reference to the drawings. FIG. 9A is a cross section along the IXa-IXa line in FIG. 2A. FIG. 9B is a cross section along the IXb-IXb line in FIG. 2A. FIG. 10A is a cross section along the Xa-Xa line in FIG. 2B. FIG. 10B is a cross section along the Xb-Xb line in FIG. 2B. FIG. 9 shows the closed state of the sliding cover 60 (the power-off state), and FIG. 10 shows the open state of the sliding cover 60 (the power-on state).

As shown in FIG. 9A, in the closed state of the sliding cover 60, the protruding component 63c is disposed above the holding space 95a. When the user slides the cover 61 down until the sliding cover 60 is in its closed state, the protruding component 63c is held inside the holding space 95a as shown in FIG. 10A. In this case, the blocking plate 95 is disposed ahead of the protruding component 63c. Accordingly, the protruding component 63c and the blocking plate 95 restrict the front plate 10 from moving away from the plastic frame 90.

As shown in FIG. 9B, in the closed state of the sliding cover 60, the knob 64 is disposed at the upper end position within the knob groove 92. When the user slides the cover 61 down until the sliding cover 60 is in its closed state, the knob 64 moves to the lower end position within the knob groove 92 and the lever 93b of the detector switch 93 is rotated downward as shown in FIG. 10B. This switches on the power to the digital camera 100.

Action and Effect

(1) The digital camera 100 pertaining to the embodiment comprises the sliding cover 60 having the protruding component 63c (one example of a “first restrictor”) that is fixed to the cover 61, and the plastic frame 90 (one example of an “internal member”) having the blocking plate 95 (one example of a “second restrictor”) that is adjacent to the protruding component 63c when the knob 64 (one example of a “detected component”) is located at the lowermost position (one example of a “specific position”). The protruding component 63c and the blocking plate 95 restrict the front plate 10 from moving away from the plastic frame 90 when the knob 64 is located at the lowermost position.

Accordingly, when the digital camera 100 should be subjected to some external force (such as an impact force caused by falling), the front plate 10 is restricted from moving away from the plastic frame 90 even if the front plate 10 bows outward. Therefore, the knob 64 can be restricted from separating from the lever 93b (one example of a “contact component”) of the detector switch 93, so the detector switch 93 is not damaged as the front plate 10 recovers elastically.

(2) With the digital camera 100 pertaining to this embodiment, the blocking plate 95 is disposed between the protruding component 63c and the front plate 10 when the knob 64 is located at the lowermost position.

Therefore, when the front plate 10 bows outward, the protruding component 63c hits the blocking plate 95, and this restricts the front plate 10 from moving away from the plastic frame 90. Thus, the front plate 10 can be restricted from moving away from the plastic frame 90 by a simple configuration, so the internal configuration of the digital camera 100 does not become more complicated.

(3) The protruding component 63c is a projection that extends into the housing, and the blocking plate 95 forms the holding space 95a for holding the protruding component 63c when the knob 64 is located at the lowermost position.

The protruding component 63c is thus held in the holding space 95a, which allows the protruding component 63c to be more securely latched to the blocking plate 95.

(4) The protruding component 63c is formed in the up and down direction (“transverse direction”), and the holding space 95a is formed in the up and down direction.

Thus, the protrusion 63c and the holding space 95a are formed in the direction in which the cover 61 slides. Accordingly, the protrusion 63 can be fitted into the holding space 95a as the cover 61 slides, so the protrusion 63 can be held in the holding space 95a by a simple configuration. Therefore, the internal configuration of the digital camera 100 does not become more complicated.

(5) The lever 93b is able to rotate around the axis perpendicular to the outer face 10S of the front plate 10. On the other hand, the lever 93b is unable to rotate around a axis parallel to the outer face 10S of the front plate 10. Accordingly, the lever 93b is susceptible to damage by being pressed backward by the knob 64. With the digital camera 100 pertaining to the embodiment, damage to the detector switch 93 can be suppressed even when using the lever 93b that is thus susceptible to damage.

(6) The lever 93b is rotated by the knob 64 when the knob 64 moves to the lowermost position. Accordingly, it can be detected with a simple configuration that the knob 64 has hit the lever 93b.

### Other Embodiments

The present invention is described by the embodiment above, but this should not be interpreted to mean that the text and drawings that form part of this disclosure limit this invention. Various substitute embodiments, working examples, and implementation techniques will probably be obvious to a person skilled in the art from this disclosure.

(A) In the above embodiment, the front plate 10 was described as an example of a “plate-like member,” but the present invention is not limited to this. Examples of the “plate-like member” include the rear plate 20, the top plate 30, the first side plate 40, and the second side plate 50.

(B) In the above embodiment, the protruding component 63c was described as an example of a “first restrictor,” and the blocking plate 95 was described as an example of a “second restrictor,” but the present invention is not limited to this. A pair of magnets with mutually different polarity or the like can be used as the “first restrictor” and the “second restrictor.”

(C) In the above embodiment, the knob 64 was described as one example of a “detected component,” but the present invention is not limited to this. A rod-like member that protrudes into the housing or the like can be used as the “detected component.”

(D) In the above embodiment, the lever 93b was described as an example of a “contact component,” but the present invention is not limited to this. A plate-like member, an elastic member (such as a spring) that expands and contracts in a transverse direction, or the like can be used as the “contact component.”

(E) In the above embodiment, the protruding component 63c protruded downward, but the present invention is not limited to this. The protruding component 63c may instead protrude in a direction other than downward. In this case, the blocking plate 95 may have a shape corresponding to the shape of the protruding component 63c.

(F) In the above embodiment, the front plate 10 was restricted from moving away from the plastic frame 90 by having the protruding component 63c hit the blocking plate 95 located in front, but the present invention is not limited to this. The protruding component 63c and the blocking plate 95 may be mechanically linked (latched).

(G) In the above embodiment, the digital camera 100 was given as an example of an “electronic device,” but the present invention is not limited to this. Examples of an “electronic device” include a video camera, a portable telephone, an IC recorder, and so forth.

Thus, the present invention of course includes various embodiments and the like that are not discussed herein. Therefore, the technological scope of the present invention is not limited to just the specific inventions pertaining to the appropriate claims from the descriptions given above.

### General Interpretation of Terms

In understanding the scope of the present disclosure, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts. Also as used herein to describe the above embodiment(s), the following directional terms “forward”, “rearward”, “above”, “downward”, “vertical”, “horizontal”, “below” and “transverse” as well as any other similar directional terms refer to those directions of a housing structure and an imaging device. Accordingly, these terms, as utilized to describe the present invention should be interpreted relative to a housing structure and an imaging device.

The term “configured” as used herein to describe a component, section or part of a device includes hardware and/or software that is constructed and/or programmed to carry out the desired function.

The terms of degree such as “substantially”, “about” and “approximately” as used herein mean a reasonable amount of deviation of the modified term such that the end result is not significantly changed.

While only selected embodiments have been chosen to illustrate the present invention, it will be apparent to those skilled in the art from this disclosure that various changes and modifications can be made herein without departing from the scope of the invention as defined in the appended claims. For example, the size, shape, location or orientation of the various components can be changed as needed and/or desired. Components that are shown directly connected or contacting each other can have intermediate structures disposed between them. The functions of one element can be performed by two, and vice versa. The structures and functions of one embodiment can be adopted in another embodiment. It is not necessary for all advantages to be present in a particular embodiment at the same time. Every feature which is unique from the prior art, alone or in combination with other features, also should be considered a separate description of further inventions by the applicant, including the structural and/or functional concepts embodied by such feature(s). Thus, the foregoing descriptions of the embodiments according to the present invention are provided for illustration only, and not for the purpose of limiting the invention as defined by the appended claims and their equivalents.

What is claimed is:

1. An electronic device comprising:
a housing defining an interior space, the housing including a plate-like member that defines a slide opening;
a sliding cover including a cover component disposed on the plate-like member and slidably attached to the slide opening along a transverse direction, a detected component fixed to the cover component and extending into the interior space of the housing, and a first restrictor fixed to the cover component; and
an internal member disposed inside the housing, the internal member including a detector switch having a contact component configured to contact the detected component when the detected component is located at a specific position, the detector switch detecting when the contact component has come into contact with the detected component, and a second restrictor disposed adjacent to the first restrictor when the detected component is located at the specific position,
the first restrictor and the second restrictor being configured to restrict the plate-like member from moving away from the internal member when the detected component is located at the specific position.

2. The electronic device according to claim 1, wherein
the second restrictor is disposed between the first restrictor and the plate-like member when the detected component is located at the specific position.

3. The electronic device according to claim 2, wherein
the first restrictor is a protruding component that extends into the interior space of the housing, and
the second restrictor defines a holding space in which the protruding component is held when the detected component is located at the specific position.

4. The electronic device according to claim 3, wherein
the protruding component extends along the transverse direction, and
the holding space extends in the transverse direction.

5. The electronic device according to any of claim 1, wherein
the contact component is configured to rotate around an axis perpendicular to an outer surface of the plate-like member.

6. The electronic device according to claim 5, wherein
the contact component is rotated by the detected component when the detected component moves to the specific position.

7. The electronic device according to claim 1, further comprising:
a power supply controller configured to start supplying current when the detector switch has detected contact between the contact component and the detected component.

8. The electronic device according to claim 7, wherein
the internal member is a frame disposed along an inner surface of the housing.

9. The electronic device according to claim 2, wherein
the first restrictor is disposed above the center part of an inner surface of the plate-like member.

10. An imaging device comprising:
a housing defining an interior space, the housing including a plate-like member that defines a slide opening;
a sliding cover including a cover component disposed on the plate-like member and slidably attached to the slide opening along a transverse direction, a detected component fixed to the cover component and extending into the interior space of the housing, and a first restrictor fixed to the cover component;
an internal member disposed inside the housing, the internal member including a detector switch having a contact component configured to contact the detected component when the detected component is located at a specific position, the detector switch detecting when the contact component has made contact with the detected component, and a second restrictor adjacent to the first restrictor when the detected component is located at the specific position; and
a lens attached to the housing,
the first restrictor and the second restrictor being configured to restrict the plate-like member from moving away from the internal member when the detected component is located at the specific position.
